(19) United States
(12) Patent Application Publication
(10) Pub. No.: US 2001/0030060 A1
(43) Pub. Date: Oct. 18, 2001

(54) Electronic component protection devices and methods

(76) Inventor: David W. Carroll, Northfield, MN (US)

Correspondence Address: William M. Hienz III, Dicke, Billig & Czaja, P.A., 701 Building, Suite 1250, 701 Fourth Avenue South, Minneapolis, MN, 55415, US

(21) Appl. No.: 09/745,853

(22) Filed: Dec. 22, 2000

Related U.S. Application Data
(60) Provisional application No. 60/171,868, filed on Dec. 23, 1999.

(51) Int. Cl. H05K 1/16

(52) U.S. Cl. 174/260

(57) ABSTRACT

A computing device unit includes a rigid-to-flexible protection mechanism for e.g. die-on-flex technologies. According to one example, a flexible electronic device includes an electronic component for generating or receiving signals, a substrate for supporting the electronic component, and structure for stiffening the substrate, the structure being disposed to provide the substrate with a first rigidity adjacent the electronic component and a second rigidity more distant from the electronic component, the first rigidity being greater than the second rigidity such that the electronic component is protected against excessive flexing.

### CROSS-REFERENCE TO RELATED APPLICATION

The subject matter of this application is related to the subject matter of U.S. patent application Ser. No. 60/171,868, filed Dec. 23, 1999, priority to which is claimed under 35 U.S.C. § 119(e) and which is incorporated by reference herein in its entirety.

### BACKGROUND OF THE INVENTION

1. Field of the Invention

Embodiments of the invention relate to flexible electronic devices. More particularly, embodiments of the invention relate to features that protect such devices, or electronic components associated with those devices, from damage by excessive bending or flexing, for example.

2. Description of Related Art

Wearable computing devices of many different types are being used in a host of commercial, industrial and consumer environments. Many such computers are brick-like, however, concentrating a great deal of weight in a bulky, cumbersome box that must be strapped onto the body.

The best wearable computers are lightweight and flexible, demonstrating superior ergonomics and allowing use during all normal activities. According to one example, flexible circuitry or equivalent flexible transmission devices join physically independent computer modules, allowing comfortable distribution of the computer about the body to accommodate a wide variety of body morphologies. Standard-interconnect input/output devices allow easy user upgrades and modular replacements. Spread-spectrum wireless Local Area Networks allow interaction with other users and/or with a host computer system. Flexible wearable computing devices are comfortable, easy-to-use, convenient and powerful alternatives to the brick-like machines that until recently have been the only choice in the marketplace.

Commonly assigned U.S. Pat. Nos. 5,285,398, 5,491,651, 5,581,492, 5,798,907, and 6,108,197 to Janik, and commonly assigned U.S. Pat. Nos. 5,555,490 and 5,572,401 to Carroll, all of which are incorporated by reference herein, disclose a number of extremely advantageous designs that provide numerous advantages over previous, box-like wearable computers.

Recently, multi-chip module, thin-film circuit, known-good-die and die-on-flex technologies have provided the potential for considerable miniaturization and standardization in personal computers. U.S. Pat. No. 5,422,514 to Griswold, for example, which is incorporated herein by reference, discloses a number of advantageous packaging structures and techniques. Griswold discloses a multi-chip module packaging structure having a thin-film decal interconnect circuit fabricated on a thin wafer of aluminum or other material. MicroModule Systems, Inc. has developed and produced a number of different multi-chip module and associated packaging products. Additionally, International Patent Applications Nos. WO 96/07143, WO 96/07921, and WO 96/07924 are incorporated herein by reference as well. Combining known-good-die, die-on-board and/or die-on-flex technologies has yielded packaging structures with significant reliability and standardization advantages.

Given the many opportunities that have arisen with the introduction of these technologies, it would be very advantageous to develop and specifically adapt these technologies in wearable-computing environments. Additionally, it would be very advantageous to develop die-on-flex technologies that can withstand the rigorous wearable-computing environment, and other environments.

### SUMMARY OF THE INVENTION

To overcome the problems associated with prior devices and to achieve various advantages, a number of computing systems and modules are described.

In one embodiment, a flexible and/or wearable computing module includes a select pattern of variable flexibility elements for providing a rigid-to-flexible stiffness pattern on the computing module. For example, in a computing module comprising a die-on-flex arrangement such as a die-type integrated circuit on a flexible carrier/substrate, the pattern is overlaid on the die or otherwise formed on or in the carrier/substrate to provide generally rigid support for the die and progressively more flexible support for the area on the carrier.

According to different embodiments of the invention, the pattern can be made from elements such as pads, disks, rings, spiral rings, or a combination thereof, with selected variable sizes and shapes of those elements to achieve the optimal progression and arrangement of variable rigidity on the flexible carrier, particularly on, underneath, and immediately surrounding the die on the flexible carrier. In some instances, the variable flexibility element(s) can be achieved using a single continuous sheet having a variable flexibility pattern formed therein.

Further, the variable flexibility elements optionally act as a conductor to a heat sink to actively aid in appropriate management of thermal radiation, or as a conduit for EMI protection to aid in management of EMI radiation.

Embodiments of the invention are well-suited to flexible and/or wearable die-on-flex environments and other manufacturing and packing technologies, and provide fast, small, durable, and cost-effective design configurations that represent significant improvements over prior-art wearable computers.

According to aspects of the invention, a die-on-flex device includes a flexible substrate, a die operably coupled with the substrate, and a stiffener pattern connected to the substrate, the stiffener pattern being constructed and arranged to provide a first area of substrate rigidity in the vicinity of the die and a second area of substrate rigidity farther away from the die, the first rigidity being greater than the second rigidity. The stiffener pattern can include a plurality of pads formed of a material at least as rigid as the flexible substrate, pads closer to the die being larger than pads farther away from the die according to one example.

The stiffener pattern can form a plurality of generally concentric shapes. Each concentric shape can be separated from an immediately adjacent concentric shape by a distance, said distance increasing with increasing distance from the die. The generally concentric shapes are generally concentric rings, according to one example. The stiffener pattern can also include a plurality of ring-shaped stiffeners, with at least one arm connecting one of the ring-shaped stiffeners to another of the ring-shaped stiffeners. The plurality of ring-shaped stiffeners together can form a single piece.

The stiffener pattern can be a spiral pattern, for example a single stiffener in a spiral shape, the single stiffener decreasing in dimension with increasing distance from the die. The stiffener pattern can be formed over said die and said flexible carrier, and/or formed between said die and said flexible carrier.

According to another aspect of the invention, a flexible electronic device includes a flexible support having a first portion and a second portion distinct from the first portion, an electronic component disposed at the first portion of the flexible support, and a stiffener arrangement, the stiffener arrangement being operably coupled with the first portion of the flexible support and with the second portion of the flexible support, wherein the stiffener arrangement is constructed and arranged to provide the first portion of the flexible support with a first rigidity and to provide the second portion of the flexible support with a second rigidity, the first rigidity being greater than the second rigidity. The electronic component can include an integrated circuit and/or a die.

At least one stiffener of the stiffener arrangement is constructed and arranged to generally prevent flexing of the first portion of the flexible support, according to one embodiment. The stiffener arrangement can comprise a plurality of stiffeners, each stiffener of the plurality of stiffeners having a predetermined width, said width decreasing with increasing distance from the die. The stiffener arrangement can be constructed of heat-transfer material to form, or transfer heat to, a heat sink. The stiffener arrangement can be formed within the flexible support.

According to aspects of the invention, the flexible electronic device can be a flexible motherboard, flexible circuitry, flexible battery, flexible touchpad for input operations, flexible display, light-emitting-polymer device, or other device.

The flexible electronic device can be formed into a three-dimensional enclosure. The electronic component can include multiple chips, and/or one or more connective devices to a flexible display. The stiffener arrangement can be a first stiffener arrangement, the flexible electronic device further including a second stiffener arrangement disposed at an opposite side from the first stiffener arrangement.

According to another aspect of the invention, a flexible electronic device comprises an electronic component for generating or receiving signals, a substrate for supporting the electronic component, and means for stiffening the substrate, the means for stiffening being disposed to provide the substrate with a first rigidity adjacent the electronic component and a second rigidity more distant from the electronic component, the first rigidity being greater than the second rigidity such that the electronic component is protected against excessive flexing.

The means for stiffening can be disposed to provide the substrate with decreasing rigidity with increasing distance from the electronic component, and can comprise a plurality of stiffeners constructed of identical material. The electronic component can comprise a die, and the flexible signal-relaying device can be a die-on-flex device. Further, the flexible electronic device can form a portion of a wearable computer.

According to another aspect, a method of protecting an electronic component against excessive flexing comprises supporting an electronic component on a substrate, the electronic component being for generating or receiving signals, and stiffening the substrate so as to provide the substrate with a first rigidity adjacent the electronic component and a second rigidity more distant from the electronic component, the first rigidity being greater than the second rigidity such that the electronic component is protected against excessive flexing. The stiffening can occur with one or more stiffeners, and the method further includes removing the one or more stiffeners from the substrate, according to one example.

### BRIEF DESCRIPTION OF THE DRAWINGS

Embodiments of the invention will be described with reference to the figures, in which like reference numerals denote like elements and in which:

FIG. 1 is a schematic illustration of a flexible and/or wearable electronic device according to embodiments of the invention;

FIG. 2 is a schematic illustration of an electronic device incorporating variable flexibility elements, according to embodiments of the invention;

FIG. 3 is a schematic illustration of variable flexibility elements substantially similar to the elements of FIG. 2, according to embodiments of the invention;

FIG. 4 is a schematic illustration of an electronic device incorporating variable flexibility elements, according to embodiments of the invention;

FIG. 5 is a schematic illustration of variable flexibility elements substantially similar to the elements of FIG. 4, according to embodiments of the invention;

FIG. 6-7 are schematic illustrations of a pattern of variable flexibility elements, according to embodiments of the invention;

FIG. 8-10 are side views of flexible and/or wearable electronic devices incorporating variable flexibility elements, according to embodiments of the invention;

FIG. 11 is a schematic top plan view of a wearable electronic device incorporating variable flexibility elements, as wom on a user according to an embodiment of the invention;

FIG. 12 is a schematic view of a flexible and/or wearable electronic device incorporating variable flexibility elements on two sides thereof, according to an embodiment of the invention;

FIG. 13 is a schematic view of one or more flexible and/or wearable electronic devices incorporating variable flexibility elements configured into a three-dimensional shape, according to an embodiment of the invention; and

FIG. 14 is a schematic view of a flexible and/or wearable electronic device incorporating variable flexibility elements stitched to a garment.

### DETAILED DESCRIPTION OF PREFERRED EMBODIMENTS

Embodiments of the invention have wide application to a number of different computing technologies and environments. As discussed above, flexible wearable computers are gaining rapid acceptance in the marketplace in different computing environments, including military, maintenance, law enforcement, medical and other environments. Further, miniaturization and ease of manufacture are important in virtually all computing environments, not just those well-suited for wearable computers. Thus, although particular embodiments of the invention are discussed with respect to wearable computers and in particular flexible wearable computers, the invention is not necessarily limited to those embodiments.

According to one, non-exclusive example, a rigid-to-flexible protection mechanism for die-on-flex technologies on flexible and/or wearable computing systems includes a pattern of stiffeners providing more rigidity on a flexible carrier/substrate in the vicinity of the die and less rigidity on the flexible carrier/substrate farther away from the die. This variable stiffness pattern protects the die-on-flex arrangement by generally preventing undue flexing of the die while permitting sufficient flexibility on the flexible carrier/substrate to accommodate desired flexibility for the flexible and/or wearable computing environment.

FIG. 1 illustrates a computer system 10 according to an embodiment of the invention. System 10 is a die-on-flex system, according to one example, including flexible substrate, carrier or support 12 and component 14. Component 14 can be an electronic or non-electronic component, e.g. a silicon die or chip or other device. In the illustrated embodiment, component 14 includes connective wires or leads 16 arranged in fan-out pattern 18. Substrate or carrier or support 12 can equally be any material or product providing support for a component for which protection is desired, and such meaning is generally intended when the term “substrate” or “carrier” is used herein. Similarly, although the term “die” may be used to refer to electronic component 14, such use is intended to illustrate other possible uses not limited strictly to an actual die. A number of specific examples according to embodiments of the invention will be described.

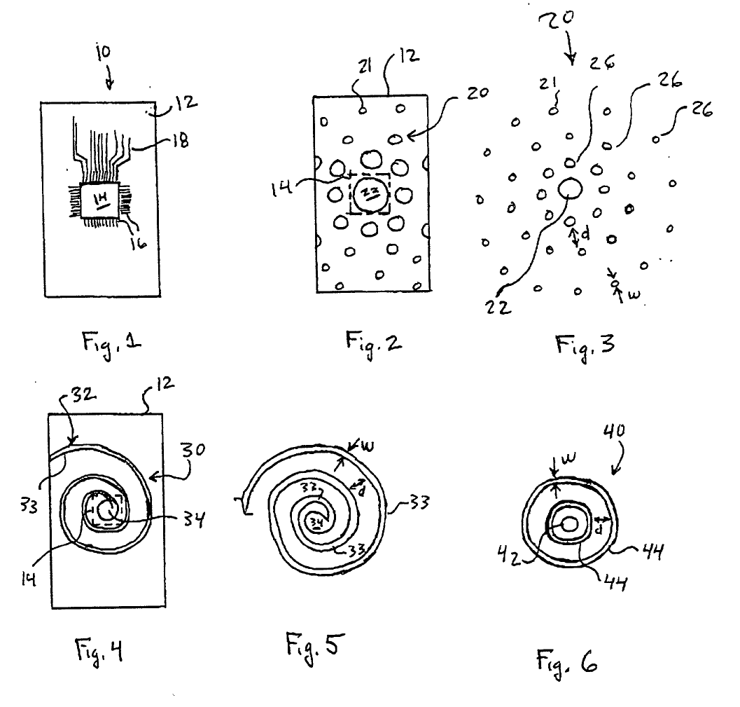

FIG. 2 illustrates flexible carrier 12 having rigid-to-flexible protection mechanism 20 formed thereon or therein. Die 14 is shown in phantom by the dotted lines. Protection mechanism 20 includes a plurality of dots or pads 21 formed of a material at least as rigid and preferably more rigid than flexible carrier 12, according to embodiments of the invention, so that the entire arrangement of mechanism 20 selectively adds stiffness to flexible carrier 12 in an optimal pattern.

According to one example, mechanism 20 has a pattern in which the greatest rigidity or stiffness is provided at the center of the pattern, such as central pad 22, which corresponds to the location of die 14. This generally ensures that die 14, which is relatively fragile, will not fail due to flexing of die 14 on flexible carrier 12. As protection mechanism 20 extends radially outward from die 14 and central pad 22, each pad 21 becomes smaller and/or less rigid, with pads 21 generally forming concentric rings 26 about central pad 22, according to the illustrated embodiment. Accordingly, protection mechanism 20 provides the greatest rigidity at die 14 with progressively less stiffness farther away from die or other electronic component 14.

The less stiff region farther away from die 14 allows some bending but is more rigid than the rigidity of the flexible carrier alone, so that wires 16 in fan out pattern 18 do not touch each other, or experience fatigue failure, due to frequent bending. Of course, application of the variable flexibility protection mechanism is not limited only to die-on-flex arrangements, but also to any e.g. electronically based product that flexes. The protection mechanism permits the product to flex variably (in any or all directions) while generally preventing flexing in an isolated region of the electronic component (e.g. die, silicon integrated circuits, controllers, connectors, processors, other electronic components, etc.) that cannot withstand flexing as readily.

FIG. 3 shows a larger schematic illustration of the pattern of FIG. 2. Protection mechanism 20 includes a distance (d) between successive concentric rings 26 of pads 21 and a width (w) corresponding to the relative width of each ring 26. Both the distance (d) and the width (w) can remain constant, or can vary. For example, the distance (d) between rings 26 preferably becomes larger as rings 26 extend radially outward from the center of the pattern, lending progressively more flexibility away from die 14. In this example, the width (w) of rings 26 remains constant or optionally becomes progressively smaller farther away from die 14.

Alternatively, the distance (d) between successive concentric rings 26 remains constant, and the width (w) of rings 26 decreases farther away from die 14 to provide the progressive flexibility that fans outwardly from die 14. Of course, the variability in either distance (d) between rings 26 or their width need not be continuous or regular. Rather, the distance (d) between rings 26 and width (w) of each ring 26 is selected to achieve the optimal variability in rigidity to flexibility in one or more directions as desired to provide greater rigidity or flexibility as needed for die 14, flexible carrier 12, and associated components and wiring 16, 18.

Moreover, the pads shown in FIGS. 2-3 need not form rings 26 but can be spaced regularly or irregularly to achieve a desired pattern of variable rigidity to flexibility. Such pads or other stiffener elements can individually be of the following shapes, or collectively can form one or more of the following shapes (in the manner that the pads form e.g. rings 26): one or more ovals, spirals, ellipses, squares, rectangles, triangles, webs, geometric shapes or patterns, random shapes or patterns, or any other regular or irregular shape or pattern for protection as desired.

FIGS. 4-5 show protection mechanism 30 on flexible carrier 12 having spiral pattern 32 of arm 33 with its center 34 at die 14. As shown in FIG. 5, successive arms 33 preferably have less width and are farther apart (d becomes greater) as spiral 32 extends radially outward from center 34 and die 14. Center 34 is sized and shaped with sufficient rigidity to prevent undue flexing of die 14 on flexible carrier 12. However, as previously described for the embodiment of FIGS. 2-3, the distance and width of arm 33 of spiral 32 are selected as necessary to provide a desired variable rigidity pattern for die 14 and flexible carrier 12.

In most applications, it is expected that spiral pattern 32 will become thinner and have greater spacing between successive concentric turns of arm 33 farther away from die 14, thereby providing greater rigidity nearer die 14 and lesser rigidity farther from die 14. Since spiral 32 is formed as one piece according to this particular embodiment, spiral 32 can be placed or formed on die 14 and/or carrier 12 (or other layer) in a single drop placement or forming step.

FIG. 6 illustrates rigid-to-flex protection mechanism 40 including center pad or disc 42 with concentric rings 44. As before, the distance (d) between rings 44 and the width (w) of each ring 44 is selected to achieve optimal variability in flexibility at, and extending away from, die 14 on flexible carrier 12. Moreover, each ring 44 need not form a perfect circle but can be made in an elliptical shape, or other shape, to optimize the desired pattern of stiffness.

As shown in FIG. 6, rings 44 may require separate formation or placement on die 14 and/or carrier 12 since there is no interconnection between rings 44.

Alternatively, a temporary carrier or ring interconnection is used to maintain selected spacing between rings 44 during formation or placement on die 14 and/or flexible carrier 12 and/or associated layering/structure.

Variable flexibility pattern 46 shown in FIG. 7 includes arms 48 that interconnect concentric rings 44 so that taken together, all of rings 44 form a single piece, thereby simplifying installation or formation on die 14 and/or carrier 12 and/or other layer associated with die 14 or carrier 12. Arms 48 also maintain spacing between rings 44.

In all of the above examples, the rings, pads, or other shaped objects forming the rigid-to-flexible protection mechanism (20, 30, 40, etc.) can be formed of any desired material, e.g. ceramic or other material. The protection mechanisms are also formed of a material that is capable of transmitting heat along the mechanism to a heat sink or is capable of transmitting EMI protection along the mechanism, or both heat and EMI protection, or neither heat nor EMI protection. Of course, the mechanism can be made of any suitable heat transfer material or for assisting in heat transfer, and can optionally be used with radiating heat means such as that available through Sandia Labs. The mechanism can also optionally be integrated to power saving materials, such as Citizen's thermocouple module based on BiSbTe and BiTe.

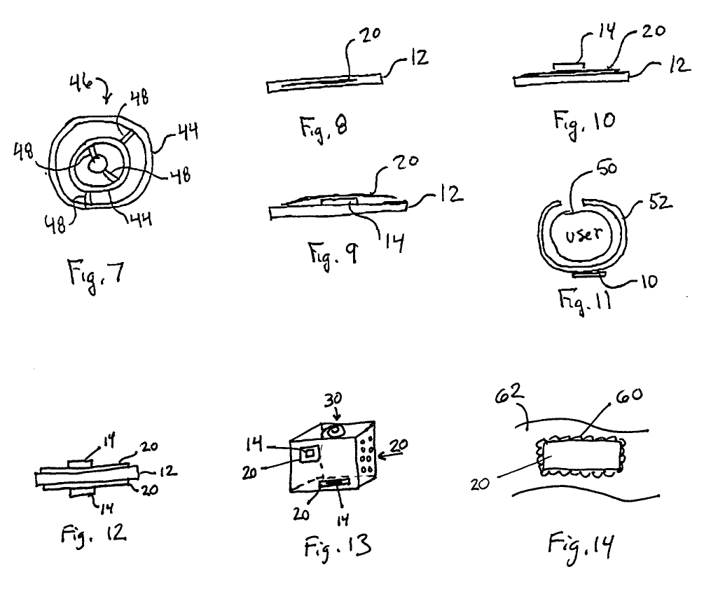

As shown in FIGS. 8-10, in all of the rigid-to-flexible protection mechanisms described above, the mechanism (e.g. mechanism 20, 30, 40, etc.) can be formed within flexible carrier 12 (FIG. 8), over die 14 and flexible carrier 12 (FIG. 9), or under die 14 and on top of flexible carrier 12 (FIG. 10). The mechanism can be implemented separately or integrally with flexible carrier/substrate 12 (or other electronic flexible design, e.g. flexible motherboard). Stiffener patterns according to embodiments of the invention can be coupled to substrate or carrier 12 in a variety of ways, including by stitching (for example in the case of a cloth-based or cloth-attached substrate), adhesive, thermally, or by a number of other modes. Stiffener pattern 12 can be aligned with webbing or other structural feature of substrate 12, aligned against the webbing or feature, or be randomly disposed with respect to substrate 12.

Moreover, the rigid-to-flexible protection mechanism can be placed in any combination of these locations or another location or layer relative to die 14 and flexible carrier 12 to enhance and accommodate the flexible nature of flexible and/or wearable computing module or system 10. In a particular embodiment, any combination is chosen that is suitable for providing greater rigidity for system 10 at support 12 to protect e.g. die 14, and e.g. its associated tightly nested wires, from flexing-type fatigue failure and for providing lesser rigidity on carrier 12 farther away from die or other component 14.

FIG. 11 shows placement of system 10 in a wearable computing environment when placed on a user 50, e.g. as a belt or connected to a belt. System 10 can take or be associated with many other wearable, pocketable or carryable forms, e.g. a wallet, PDA, purse, bag, calculator, etc.

Embodiments of the invention contemplate additional specific features and examples. According to one example, substrate, support or carrier 12 is or has a multi-layer board, e.g. an eight-layer board, one or more of the layers being a copper layer or otherwise being formed of one or more conductive materials. A stiffener pattern according to any of the above-described embodiments can be placed in, on, or in association with the board before or after the die or other component is placed. In one example, the stiffener pattern constitutes or is formed as a part of one of the layers, or more than one of the layers, either before or after the die is placed in association with the board or board population otherwise occurs, to form one or more flex management layers.

According to embodiments of the invention, one or more electronic components can be located in one or more relatively stiff regions of substrate 12, and each component can include one or more connectors or chips for a display, e.g. a flexible display, or other electronic device. Alternatively, or additionally, substrate 12 can constitute or be a part of a flexible display, with one or more stiffeners according to the above-described examples being incorporated within and/or on substrate 12. Flexible displays produced and/or discussed by Cambridge Display Technology, Cambridge, UK, for example, are among those suited for use according to embodiments of the invention. Light emitting polymer (LEP) displays, LEP single or multiple pixel devices fabricated on e.g. flexible polyester substrates, conjugated polymers for displays, and displays and associated technology related to or incorporating U.S. Pat. Nos. 5,247,190 and 5,399,502, both of which are incorporated herein by reference, are among those readily adaptable to and useable with embodiments of the invention. Thus, the foregoing are examples of electronic devices that can be or be akin to substrate/carrier 12, having or being associated with areas of differing rigidity and/or stiffeners according to embodiments of the invention. Flexible chips and other chips that are a part of displays according to the technologies described above can be protected according to embodiments of the invention. Embodiments of the invention can be added to already existing displays and other technologies, and/or be produced as the displays, etc. themselves are produced. Flexible batteries can also comprise carrier/support 12, as can flexible touchpads e.g. for input operations to a computing device, cellular phone or other communications and/or computing device.

According to embodiments of the invention, multiple “patches” of stiffness/protection can be formed throughout carrier or substrate 12. Some patches can be more rigid or solid; others can be less so, depending on the degree of protection desired for a particular associated electronic component or other device/area in which bending or flexing is not desirable. Such patches can be of the same shape or of different shapes. Such patches or areas can also overlap, according to embodiments of the invention, creating any desired pattern of rigidity or flexibility over the entire extent of the substrate/carrier or over one or more localized regions thereof.

Any of the patterns and/or stiffeners 20, 30, etc. described herein can be incorporated into and/or onto both sides of carrier/substrate 12 or other electronic device, as shown in e.g. FIG. 12. A pattern on one side may be all that is needed for a particular application, but multiple patterns on one or both sides, working with or against each other, are also contemplated.

Embodiments of the invention can be incorporated into a variety of materials or products having various degrees of elasticity or “stretchiness,” even varying elasticity within the same product. The combination of stiffener(s) or stiffener pattern(s) and varying stretchability in the carrier/substrate 12 or other product or material can yield an advantageous, synergistic effect. The carrier/substrate 12 or other product or material can include more elasticity in areas where more bending is desired, and more rigidity in areas where more protection is desired. Embodiments of the invention can be incorporated into a sheet of material that e.g. is cut out of a larger piece of material in a desired pattern. Stiffener(s) according to the invention can be applied and then removed, e.g. for washing of the underlying substrate in the case of an electronic garment or other cloth-based support. Snap-in or other attachment mechanisms are contemplated to connect such stiffener(s) at various locations and may also be part of the overall design of varying flexibility.

Stiffener patterns according to the invention can be multi-colored or of a single color, in accordance with a color scheme present on substrate/carrier 12 or to enhance one or more aspects thereof. Alternatively, or additionally, substrate/carrier 12 can be clear/transparent or translucent, to allow viewing of underlying electronics or structure.

Stiffener patterns according to the invention can be coupled with one or more substrates/supports 12 to provide more or less flexibility as may be desirable to allow substrate/support 12 to form a specific three-dimensional shape, e.g. a box or enclosure as shown in FIG. 13, cube, pyramid, sphere, cone, curve, enclosure optionally for another device, container, etc. Such shapes can be reconfigurable, e.g. bent or flexed to be rearranged or re-formed into the same or different shapes. Such shapes can provide improved configurations for transport, for wearability, and/or for user-interface purposes, such as a flexible or semi-flexible design to provide a sheet for a display, or create a laptop or laptop-compatible configuration, or create a surface for electrical and/or physical connection to a keyboard, for example.

FIG. 14 is a schematic view of a system 10 incorporating variable flexibility mechanisms 20, 30, etc. as described herein stitched at 60 to garment 62, e.g. a wearable electronic garment or another garment that supports or comprises one or more electronic devices, e.g. CD players, MP3 players, other entertainment devices, cellular telephones, pagers, other communication and/or computing devices, etc.

Embodiments of the invention can incorporate or be associated with a linear array noise-canceling microphone protection pattern aimed or configured in an appropriate direction for the user and/or one or more other individuals with whom the user is speaking.

While the invention has been described with reference to specific embodiments, the description is illustrative and is not to be construed as limiting the scope of the invention. For example, individual features or elements of any of the various disclosed embodiments can be combined to suit a particular application. Additionally, the illustrated and described features can be used with not only wearable computers but also with other types of computing devices and electronic devices. Wireless or wired, infrared, optical, and other communication schemes are contemplated. Instead of flexible circuitry, ribbon or otherwise, additional signal-relaying componentry can be used in all embodiments of the invention. By “signal” is meant power signals, data signals, and other electrical, optical, IR, RF or other signals providing transmission and/or communication. Electronic components contemplated for protection on substrate 12 according to embodiments of the invention include die, dice, silicon integrated circuits, controllers, processors, chips, multi-chip modules, connectors, displays or portions of displays, and other electronic components, a number of which are described or referenced above. Various other modifications and changes may occur to those skilled in the art without departing from the spirit and scope of the invention.

What is claimed is:

1. A die-on-flex device, comprising:
a flexible substrate;
a die operably coupled with the substrate; and
a stiffener pattern connected to the substrate, the stiffener pattern being constructed and arranged to provide a first area of substrate rigidity in the vicinity of the die and a second area of substrate rigidity farther away from the die, the first rigidity being greater than the second rigidity.

2. The die-on-flex device of claim 1, wherein the stiffener pattern comprises a plurality of pads formed of a material at least as rigid as the flexible substrate.

3. The die-on-flex device of claim 2, wherein pads closer to the die are larger than pads farther away from the die, to provide greater rigidity closer to the die.

4. The die-on-flex device of claim 1, wherein the stiffener pattern forms a plurality of generally concentric shapes.

5. The die-on-flex device of claim 4, wherein each concentric shape is separated from an immediately adjacent concentric shape by a distance, said distance increasing with increasing distance from the die.

6. The die-on-flex device of claim 4, wherein the generally concentric shapes are generally concentric rings.

7. The die-on-flex device of claim 1, wherein the stiffener pattern comprises a plurality of ring-shaped stiffeners.

8. The die-on-flex device of claim 7, further comprising at least one arm connecting one of the ring-shaped stiffeners to another of the ring-shaped stiffeners.

9. The die-on-flex device of claim 7, wherein the plurality of ring-shaped stiffeners together form a single piece.

10. The die-on-flex device of claim 1, wherein the stiffener pattern is a spiral pattern.

11. The die-on-flex device of claim 10, wherein the stiffener pattern comprises a single stiffener in a spiral shape, the single stiffener decreasing in dimension with increasing distance from the die.

12. The die-on-flex device of claim 1, wherein the stiffener pattern is formed over said die and said flexible substrate.

13. The die-on-flex device of claim 1, wherein the stiffener pattern is formed between said die and said flexible substrate.

14. A flexible electronic device, the flexible electronic device comprising:
a flexible support having a first portion and a second portion distinct from the first portion;
an electronic component disposed at the first portion of the flexible support; and
a stiffener arrangement, the stiffener arrangement being operably coupled with the first portion of the flexible support and with the second portion of the flexible support;
wherein the stiffener arrangement is constructed and arranged to provide the first portion of the flexible support with a first rigidity and to provide the second portion of the flexible support with a second rigidity, the first rigidity being greater than the second rigidity.

15. The flexible electronic device of claim 14, wherein the electronic component comprises an integrated circuit.

16. The flexible electronic device of claim 14, wherein the electronic component comprises a die.

17. The flexible electronic device of claim 14, wherein at least one stiffener of the stiffener arrangement is constructed and arranged to generally prevent flexing of the first portion of the flexible support.

18. The flexible electronic device of claim 14, wherein the stiffener arrangement comprises a plurality of stiffeners, each stiffener of the plurality of stiffeners having a predetermined width, said width decreasing with increasing distance from the die.

19. The flexible electronic device of claim 14, wherein the stiffener arrangement is constructed of heat-transfer material to form, or transfer heat to, a heat sink.

20. The flexible electronic device of claim 14, wherein the stiffener arrangement is formed within the flexible support.

21. The flexible electronic device of claim 14, wherein the flexible electronic device is a flexible motherboard.

22. The flexible electronic device of claim 14, wherein the flexible electronic device is flexible circuitry.

23. The flexible electronic device of claim 14, wherein the flexible electronic device is a flexible battery.

24. The flexible electronic device of claim 14, wherein the flexible electronic device is a flexible touchpad for input operations.

25. The flexible electronic device of claim 14, wherein the flexible electronic device is a flexible display.

26. The flexible electronic device of claim 14, wherein the flexible electronic device is a light-emitting-polymer device.

27. The flexible electronic device of claim 14, wherein the flexible electronic device is formed into a three-dimensional enclosure.

28. The flexible electronic device of claim 14, wherein the electronic component comprises multiple chips.

29. The flexible electronic device of claim 14, wherein the electronic component comprises one or more connective devices to a flexible display.

30. The flexible electronic device of claim 14, wherein the stiffener arrangement is a first stiffener arrangement, the flexible electronic device further comprising a second stiffener arrangement disposed at an opposite side of the flexible support from the first stiffener arrangement.

31. A flexible electronic device, comprising:
an electronic component for generating or receiving signals;
a substrate for supporting the electronic component; and
means for stiffening the substrate, the means for stiffening being disposed to provide the substrate with a first rigidity adjacent the electronic component and a second rigidity more distant from the electronic component, the first rigidity being greater than the second rigidity such that the electronic component is protected against excessive flexing.

32. The flexible signal-relaying device of claim 31, wherein the means for stiffening is disposed to provide the substrate decreasing rigidity with increasing distance from the electronic component.

33. The flexible signal-relaying device of claim 31, wherein the means for stiffening comprises a plurality of stiffeners constructed of identical material.

34. The flexible signal-relaying device of claim 31, wherein the electronic component comprises a die.

35. The flexible signal-relaying device of claim 31, wherein the flexible electronic device is a die-on-flex device.

36. The flexible signal-relaying device of claim 31, wherein the flexible electronic device forms a portion of a wearable computer.

37. A method of protecting an electronic component against excessive flexing, the method comprising:
supporting an electronic component on a substrate, the electronic component being for generating or receiving signals; and
stiffening the substrate so as to provide the substrate with a first rigidity adjacent the electronic component and a second rigidity more distant from the electronic component, the first rigidity being greater than the second rigidity such that the electronic component is protected against excessive flexing.

38. The method of claim 37, wherein said stiffening occurs with one or more stiffeners, the method further comprising:
removing the one or more stiffeners from the substrate.
